(19) United States
(12) Patent Application Publication
(10) Pub. No.: US 2018/0346640 A1
(43) Pub. Date: Dec. 6, 2018

(54) FILM FOR FLIP CHIP TYPE SEMICONDUCTOR BACK SURFACE, PROCESS FOR PRODUCING STRIP FILM FOR SEMICONDUCTOR BACK SURFACE, AND FLIP CHIP TYPE SEMICONDUCTOR DEVICE

(71) Applicant: NITTO DENKO CORPORATION, Osaka (JP)

(72) Inventors: Goji SHIGA, Osaka (JP); Naohide TAKAMOTO, Osaka (JP); Fumiteru ASAI, Osaka (JP)

(73) Assignee: NITTO DENKO CORPORATION, Osaka (JP)

(21) Appl. No.: 16/059,750

(22) Filed: Aug. 9, 2018

Related U.S. Application Data
(63) Continuation of application No. 13/191,574, filed on Jul. 27, 2011.

(30) Foreign Application Priority Data
Jul. 28, 2010 (JP) 2010-169559

(51) Int. Cl. C08G 59/62; C09J 163/00; C08L 63/00; B32B 27/38; C08K 3/36

(52) U.S. Cl. CPC C08G 59/621; C09J 163/00; C08L 63/00; C08K 3/36; Y10T 83/04; Y10T 428/31511; H01L 2224/16225; B32B 27/38

(57) ABSTRACT

The present invention relates to a film for flip chip type semiconductor back surface to be formed on a back surface of a semiconductor element flip chip-connected onto an adherend, the film for flip chip type semiconductor back surface having a ratio of A/B falling within a range of 1 to 8×10³ (%/GPa), in which A is an elongation ratio (%) of the film for flip chip type semiconductor back surface at 23° C. before thermal curing and B is a tensile storage modulus (GPa) of the film for flip chip type semiconductor back surface at 23° C. before thermal curing.

### CROSS REFERENCE TO RELATED APPLICATIONS

This application is a continuation of U.S. application Ser. No. 13/191,574, filed Jul. 27, 2011, which claims priority from JP 2010-169559 filed Jul. 28, 2010, the contents of all of which are incorporated herein by reference in their entirety.

### FIELD OF THE INVENTION

The present invention relates to a film for flip chip type semiconductor back surface. Also, the invention relates to a process for producing a strip film for semiconductor back surface using a film for flip chip type semiconductor back surface and to a flip chip-mounted semiconductor device.

### BACKGROUND OF THE INVENTION

Recently, thinning and miniaturization of a semiconductor device and its package have been increasingly demanded. Therefore, as the semiconductor device and its package, flip chip type semiconductor devices in which a semiconductor element such as a semiconductor chip is mounted (flip chip-connected) on a substrate by means of flip chip bonding have been widely utilized. In such flip chip connection, a semiconductor chip is fixed to a substrate in a form where a circuit face of the semiconductor chip is opposed to an electrode-formed face of the substrate. In such a semiconductor device or the like, there may be a case where the back surface of the semiconductor chip is protected with a protective film to prevent the semiconductor chip from damaging or the like (see, Patent Document 1 to 10).

Patent Document 1: JP-A-2008-166451

Patent Document 2: JP-A-2008-006386

Patent Document 3: JP-A-2007-261035

Patent Document 4: JP-A-2007-250970

Patent Document 5: JP-A-2007-158026

Patent Document 6: JP-A-2004-221169

Patent Document 7: JP-A-2004-214288

Patent Document 8: JP-A-2004-142430

Patent Document 9: JP-A-2004-072108

Patent Document 10: JP-A-2004-063551

The present inventors have made investigations on a method of attaching a film on the back surface of a semiconductor chip. As a result, they have invented a method including (1) cutting a film for flip chip type semiconductor back surface into a prescribed width according to the width of a back surface of a semiconductor element (e.g., a semiconductor chip) to form a strip film for semiconductor back surface, (2) further cutting the strip film for semiconductor back surface according to the shape of the back surface of the semiconductor element, and (3) attaching the cut film for flip chip type semiconductor back surface (strip film for semiconductor back surface) to the back surface of the semiconductor element. However, when the method is adopted, there arise new problems that cutting accuracy of the cut film for flip chip type semiconductor back surface is low in some cases, thus the film cannot be attached to the back surface of the semiconductor element with good accuracy and that cracking and chipping are generated at the cut surface.

### SUMMARY OF THE INVENTION

The present invention has been made in consideration of the foregoing problem and an object thereof is to provide a film for flip chip type semiconductor back surface capable of maintaining high cutting accuracy of the film for flip chip type semiconductor back surface and suppressing or preventing the cracking and chipping.

In order to solve the foregoing related-art problems, the present inventors have made extensive and intensive investigations. As a result, it has been found that, when an elongation ratio of the film for flip chip type semiconductor back surface at 23° C. before thermal curing is taken as A (%) and a tensile storage modulus of the film for flip chip type semiconductor back surface at 23° C. before thermal curing is taken as B (GPa), the film for flip chip type semiconductor back surface can be cut into a prescribed width with excellent width accuracy and also the cracking and chipping can be suppressed or prevented by controlling a ratio of A/B within a prescribed range, leading to accomplishment of the invention.

Namely, the present invention relates to a film for flip chip type semiconductor back surface to be formed on a back surface of a semiconductor element flip chip-connected onto an adherend, the film for flip chip type semiconductor back surface having a ratio of A/B falling within a range of 1 to 8×10³ (%/GPa), wherein A is an elongation ratio (%) of the film for flip chip type semiconductor back surface at 23° C. before thermal curing and B is a tensile storage modulus (GPa) of the film for flip chip type semiconductor back surface at 23° C. before thermal curing.

In the film for flip chip type semiconductor back surface, in order to reinforce the chip during the steps of semiconductor production, at least a certain degree of hardness, i.e., at least a certain degree of tensile storage modulus is required. Such a film having a high tensile storage modulus is generally difficult to stretch. However, in the case where the film for flip chip type semiconductor back surface is cut into a prescribed width, it is necessary to cut it without generating cracking or chipping on the cut surface at the cutting and with excellent width accuracy, so that the film is required to have some degree of a stretchable property.

According to the foregoing constitution, when an elongation ratio of the film for flip chip type semiconductor back surface at 23° C. before thermal curing is taken as A and a tensile storage modulus of the film for flip chip type semiconductor back surface at 23° C. before thermal curing is taken as B, a ratio of A/B falls within a range of 1 to 8×10³ (%/GPa). Since the ratio of A/B is 1 to 8×10³, the film for flip chip type semiconductor back surface has some degree of hardness and has some degree of the stretchable property. Therefore, at the cutting, it becomes possible to cut the film into a prescribed width with excellent width accuracy. Moreover, at the cutting, the generation of cracking and chipping on the cut surface can be suppressed. As above, since the film for flip chip type semiconductor back surface of the invention can be cut with good accuracy according to the shape of the back surface of the semiconductor element, the film can be attached to the back surface of the semiconductor element with good accuracy and also an influence of contamination with foreign particles resulting from the cracking and chipping on the cut surface can be diminished to a large extent.

In the foregoing constitution, the tensile storage modulus preferably falls within a range of 0.01 to 4.0 GPa. When the tensile storage modulus is 0.01 GPa or more, the film for semiconductor back surface can be cut without deformation during the production steps and can be cut with good accuracy according to the shape of the back surface of the semiconductor element. On the other hand, when the tensile storage modulus is 4.0 GPa or less, the film for semiconductor back surface can be cut without cracking and chipping on the cut surface thereof and the influence of contamination with foreign particles can be diminished to a large extent.

In the foregoing constitution, it is preferred that the film for flip chip type semiconductor back surface contains an epoxy resin and a phenol resin, the total amount of the epoxy resin and the phenol resin falls within a range of 5 to 90% by weight based on the total resin components of the film for flip chip type semiconductor back surface, and the epoxy resin and the phenol resin each have a melting point of 25° C. or lower. When the total amount of the epoxy resin and the phenol resin falls within a range of 5 to 90% by weight based on the total resin components of the film for flip chip type semiconductor back surface and the epoxy resin and the phenol resin each have a melting point of 25° C. or lower, the tensile storage modulus before thermal curing can be maintained high and also the elongation ratio before thermal curing can be made high.

The present invention also provides a process for producing a strip film for semiconductor back surface, the process comprising cutting the above-mentioned film for flip chip type semiconductor back surface into a prescribed width to obtain the strip film for semiconductor back surface.

According to the foregoing constitution, there is used a film for flip chip type semiconductor back surface wherein, when the elongation ratio at 23° C. before thermal curing is taken as A and the tensile storage modulus at 23° C. before thermal curing is taken as B, a ratio of A/B falls within a range of 1 to 8×10³ (%/GPa), so that it becomes possible to obtain a strip film for semiconductor back surface cut into a prescribed width with excellent width accuracy.

The present invention further provides a flip chip type semiconductor device, which is manufactured using the strip film for semiconductor back surface produced by the process for producing a strip film for semiconductor back surface.

### BRIEF DESCRIPTION OF THE DRAWINGS

FIG. 1 is a cross-sectional schematic view showing one example of a film for semiconductor device production containing the film for flip chip type semiconductor back surface according to the present embodiment.

FIGS. 2A to 2D are cross-sectional schematic views showing one example of a process for producing a semiconductor device in the case of using the film for semiconductor device production shown in FIG. 1.

FIGS. 3A and 3B are cross-sectional schematic views showing one example of a process for producing a semiconductor device in the case of using the film for semiconductor device production shown in FIG. 1.

### DESCRIPTION OF REFERENCE NUMERALS AND SIGNS

2: Film for flip chip type semiconductor back surface
4: Semiconductor wafer
40: Film for semiconductor device production
42: Separator
5: Semiconductor chip
51: Bump formed on circuit surface side of semiconductor chip 5
6: Adherend
61: Conductive material for conjunction adhered to connection pad of adherend 6

### BEST MODE FOR CARRYING OUT THE INVENTION

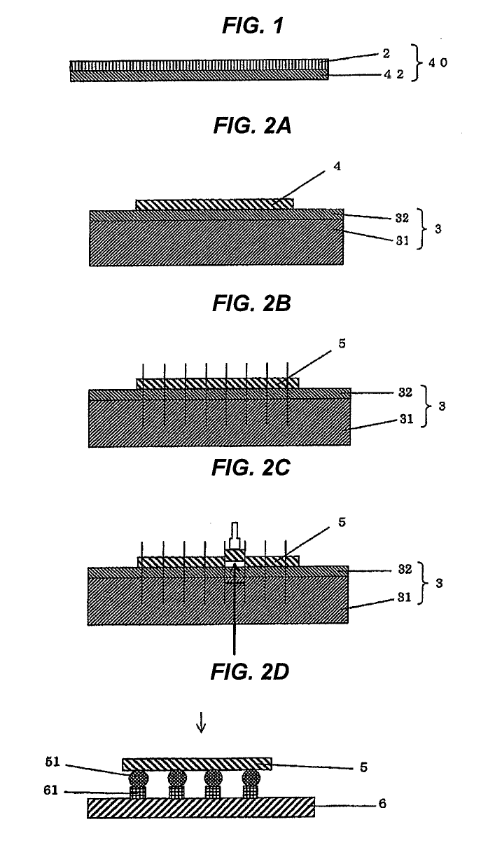

An embodiment of the invention is described with reference to FIG. 1, but the invention is not restricted to this embodiment. FIG. 1 is a cross-sectional schematic view showing one example of a film for semiconductor device production containing the film for flip chip type semiconductor back surface according to the present embodiment. Incidentally, in the figures in the present specification, parts that are unnecessary for the description are not given, and there are parts shown by magnifying, minifying, etc. in order to make the description easy.

### (Film for Flip Chip Type Semiconductor Back Surface)

The film 2 for flip chip type semiconductor back surface (hereinafter, also referred to as “film for semiconductor back surface” or “semiconductor back surface protective film”) has a film shape. The film 2 for semiconductor back surface is cut into a prescribed width according to the width of a back surface of a semiconductor chip and is used as a strip film for semiconductor back surface.

The film 2 for semiconductor back surface may be a form of a film 40 for semiconductor device production having a separator 42 laminated on one surface thereof (downside in FIG. 1). The separator 42 is peeled from the film 2 for semiconductor back surface after attached to the semiconductor chip together with the film 2 for semiconductor back surface. In the invention, the film for flip chip type semiconductor back surface may be laminated with the separator on both surfaces thereof. Moreover, the film may not be laminated with the separator and may be a film for flip chip type semiconductor back surface alone.

In the film 2 for semiconductor back surface, when the elongation ratio of the film at 23° C. before thermal curing is taken as A (hereinafter also referred to as “elongation ratio A”) and the tensile storage modulus of the film at 23° C. before thermal curing is taken as B (hereinafter also referred to as “tensile storage modulus B”), a ratio of A/B falls within a range of 1 to 8×10³ (%/GPa). The ratio of A/B preferably falls within a range of 2 to 7×10³ (%/GPa), more preferably within a range of 3 to 6×10³ (%/GPa).

In the film 2 for semiconductor back surface, in order to reinforce the chip during the steps of semiconductor production, at least a certain degree of hardness, i.e., at least a certain degree of tensile storage modulus is required. Such a film having a high tensile storage modulus is generally difficult to stretch. However, in the case where the film for flip chip type semiconductor back surface is cut into a prescribed width, for the reason of suppressing or preventing the generation of cracking or chipping on the cut surface of the film for semiconductor back surface, the film is required to have some degree of a stretchable property. Since the ratio of A/B is 1 to 8×10³, the film 2 for semiconductor back surface has some degree of hardness and has some degree of the stretchable property. Therefore, at the cutting, it becomes possible to cut the film into a prescribed width with excellent width accuracy. Moreover, at the cutting, the generation of cracking and chipping on the cut surface can be suppressed. As above, since the film 2 for semiconductor back surface can be cut with good accuracy according to the shape of the back surface of the semiconductor element, the film can be attached to the back surface of the semiconductor element with good accuracy and also an influence of contamination with foreign particles resulting from the cracking and chipping on the cut surface can be diminished to a large extent.

The film for semiconductor back surface is preferably formed of at least a thermosetting resin and is more preferably formed of at least a thermosetting resin and a thermoplastic resin. When the film is formed of at least a thermosetting resin, the film for semiconductor back surface can effectively exhibit a function as an adhesive layer.

Examples of the thermoplastic resin include natural rubber, butyl rubber, isoprene rubber, chloroprene rubber, an ethylene-vinyl acetate copolymer, an ethylene-acrylic acid copolymer, an ethylene-acrylic acid ester copolymer, a polybutadiene resin, a polycarbonate resin, a thermoplastic polyimide resin, a polyamide resin such as 6-nylon and 6,6-nylon, a phenoxy resin, an acrylic resin, a saturated polyester resin such as PET (polyethylene terephthalate) or PBT (polybutylene terephthalate), a polyamideimide resin, or a fluorine resin. The thermoplastic resin may be employed singly or in a combination of two or more kinds. Among these thermoplastic resins, an acrylic resin containing a small amount of ionic impurities, having high heat resistance and capable of securing reliability of a semiconductor element is especially preferable.

The acrylic resins are not particularly restricted, and examples thereof include polymers containing one kind or two or more kinds of esters of acrylic acid or methacrylic acid having a straight chain or branched alkyl group having 30 or less carbon atoms, preferably 4 to 18 carbon atoms, more preferably 6 to 10 carbon atoms, and especially 8 or 9 carbon atoms as component(s). Namely, in the invention, the acrylic resin has a broad meaning also including a methacrylic resin. Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (lauryl group), a tridecyl group, a tetradecyl group, a stearyl group, and an octadecyl group.

Moreover, other monomers for forming the acrylic resins (monomers other than the alkyl esters of acrylic acid or methacrylic acid in which the alkyl group is one having 30 or less carbon atoms) are not particularly restricted, and examples thereof include carboxyl group-containing monomers such as acrylic acid, methacrylic acid, carboxylethyl acrylate, carboxylpentyl acrylate, itaconic acid, maleic acid, fumaric acid, and crotonic acid; acid anhydride monomers such as maleic anhydride and itaconic anhydride; hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)-methylacrylate; sulfonic acid group-containing monomers such as styrenesulfonic acid, allylsulfonic acid, 2-(meth)acrylamido-2-methylpropanesulfonic acid, (meth)acrylamidopropanesulfonic acid, sulfopropyl (meth)acrylate, and (meth)acryloyloxynaphthalenesulfonic acid; and phosphoric acid group-containing monomers such as 2-hydroxyethylacryloyl phosphate. In this regard, the (meth)acrylic acid means acrylic acid and/or methacrylic acid, (meth)acrylate means acrylate and/or methacrylate, (meth)acryl means acryl and/or methacryl, etc., which shall be applied over the whole specification.

Moreover, examples of the thermosetting resin include, in addition to an epoxy resin and a phenol resin, an amino resin, an unsaturated polyester resin, a polyurethane resin, a silicone resin and a thermosetting polyimide resin. The thermosetting resin may be employed singly or in a combination of two or more kinds. As the thermosetting resin, an epoxy resin containing only a small amount of ionic impurities which corrode a semiconductor element is suitable. Also, the phenol resin is suitably used as a curing agent of the epoxy resins.

The epoxy resin is not particularly restricted and, for example, a difunctional epoxy resin or a polyfunctional epoxy resin such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a biphenyl type epoxy resin, a naphthalene type epoxy resin, a fluorene type epoxy resin, a phenol novolak type epoxy resin, an o-cresol novolak type epoxy resin, a trishydroxyphenylmethane type epoxy resin and a tetraphenylolethane type epoxy resin, or an epoxy resin such as a hydantoin type epoxy resin, a trisglycidylisocyanurate type epoxy resin or a glycidylamine type epoxy resin may be used. Among them, those having a melting point of 25° C. or lower are preferable.

As the epoxy resin, among those exemplified above, a novolak type epoxy resin, a biphenyl type epoxy resin, a trishydroxyphenylmethane type epoxy resin, and a tetraphenylolethane type epoxy resin are preferable. This is because these epoxy resins have high reactivity with a phenol resin as a curing agent and are superior in heat resistance and the like.

Furthermore, the above-mentioned phenol resin acts as a curing agent of the epoxy resin, and examples thereof include novolak type phenol resins such as phenol novolak resins, phenol aralkyl resins, cresol novolak resins, tert-butylphenol novolak resins, and nonylphenol novolak resins; resol type phenol resins; and polyoxystyrenes such as poly-p-oxystyrene. The phenol resin may be employed singly or in a combination of two or more kinds. Among these phenol resins, phenol novolak resins and phenol aralkyl resins are especially preferable. This is because connection reliability of the semiconductor device can be improved. Among them, those having a melting point of 25° C. or lower are preferable.

The mixing proportion of the epoxy resin to the phenol resin is preferably made, for example, such that the hydroxyl group in the phenol resin becomes 0.5 equivalents to 2.0 equivalents per equivalent of the epoxy group in the epoxy resin component. It is more preferably 0.8 equivalents to 1.2 equivalents. Namely, when the mixing proportion is outside the range, a curing reaction does not proceed sufficiently, and the characteristics of the epoxy resin cured product tends to deteriorate.

The content of the thermosetting resin is preferably 5% by weight to 90% by weight, more preferably 10% by weight to 85% by weight, further preferably 15% by weight to 80% by weight based on the total resin components of the film for semiconductor back surface. By controlling the content to 5% by weight or more, heat resistance can be held. Moreover, in the case where the film for semiconductor back surface is attached to the semiconductor chip before the step of resin encapsulation, the film for semiconductor back surface can be sufficiently thermally cured at the thermal curing of the encapsulating resin and thus can be surely adhered and fixed to the back surface of the semiconductor element to produce a flip chip type semiconductor device exhibiting no peeling. On the other hand, by controlling the content to 90% by weight or less, warp of a package (PKG: a flip chip type semiconductor device) can be suppressed.

The thermosetting resin preferably contains an epoxy resin and a phenol resin. In particular, it is preferred that the total amount of the epoxy resin and the phenol resin falls within a range of 5 to 90% by weight based on the total resin components of the film for flip chip type semiconductor back surface, and the epoxy resin and the phenol resin each have a melting point of 25° C. or lower. The total amount of the epoxy resin and the phenol resin more preferably falls within a range of 10 to 85% by weight, further preferably within a range of 15 to 80% by weight. When the total amount of the epoxy resin and the phenol resin falls within a range of 5 to 90% by weight based on the total resin components of the film for semiconductor back surface and the epoxy resin and the phenol resin each have a melting point of 25° C. or lower, the tensile storage modulus before thermal curing can be maintained high and also the elongation ratio before thermal curing can be made high.

A thermal curing-accelerating catalyst for the epoxy resins and the phenol resins is not particularly restricted and can be suitably selected from known thermal curing-accelerating catalysts and used. The thermal curing-accelerating catalyst may be employed singly or in a combination of two or more kinds. As the thermal curing-accelerating catalyst, for example, an amine-based curing-accelerating catalyst, a phosphorus-based curing-accelerating catalyst, an imidazole-based curing-accelerating catalyst, a boron-based curing-accelerating catalyst, or a phosphorus-boron-based curing-accelerating catalyst can be used.

The film for semiconductor back surface is preferably formed of a resin composition containing an epoxy resin and a phenol resin or a resin composition containing an epoxy resin, a phenol resin, and an acrylic resin. Since these resins are small in ionic impurities and high in heat resistance, reliability of a semiconductor element can be secured.

It is important that the film 2 for semiconductor back surface has adhesiveness (close adhesion) to the back surface (non-circuit face) of the semiconductor wafer. The film 2 for semiconductor back surface can be, for example, formed of a resin composition containing an epoxy resin as a thermosetting resin. For the purpose of crosslinking the film 2 for semiconductor back surface to some extent beforehand, a polyfunctional compound capable of reacting with a molecular chain terminal functional group or the like of a polymer is preferably added as a crosslinking agent at the preparation. According to this, it is possible to enhance an adhesive characteristic under high temperatures and to improve heat resistance.

An adhesive force of the film for semiconductor back surface to the semiconductor element (23° C., a peeling angle of 180°, a peeling rate of 300 mm/min) preferably falls within a range of 0.5 N/20 mm to 15 N/20 mm, more preferably 0.7 N/20 mm to 10 N/20 mm. When the adhesive force is 0.5 N/20 mm or more, the film is adhered to the semiconductor element with excellent adhesiveness and can be prevented from generation of lifting or the like. On the other hand, by controlling the adhesive force to 15 N/20 mm or less, the film can be easily peeled from the separator 42.

The crosslinking agent is not particularly restricted and known crosslinking agents can be used. Specifically, for example, not only isocyanate-based crosslinking agents, epoxy-based crosslinking agents, melamine-based crosslinking agents, and peroxide-based crosslinking agents but also urea-based crosslinking agents, metal alkoxide-based crosslinking agents, metal chelate-based crosslinking agents, metal salt-based crosslinking agents, carbodiimide-based crosslinking agents, oxazoline-based crosslinking agents, aziridine-based crosslinking agents, amine-based crosslinking agents, and the like may be mentioned. As the crosslinking agent, an isocyanate-based crosslinking agent or an epoxy-based crosslinking agent is suitable. The crosslinking agent may be used singly or in a combination of two or more kinds.

Examples of the isocyanate-based crosslinking agents include lower aliphatic polyisocyanates such as 1,2-ethylene diisocyanate, 1,4-butylene diisocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanate, and hydrogenated xylylene diisocyanate; and aromatic polyisocyanates such as 2,4-tolylene diisocyanate, 2,6-tolylene diisocyanate, 4,4′-diphenylmethane diisocyanate, and xylylene diisocyanate. In addition, a trimethylolpropane/tolylene diisocyanate trimer adduct [a trade name “COLONATE L” manufactured by Nippon Polyurethane Industry Co., Ltd.], a trimethylolpropane/hexamethylene diisocyanate trimer adduct [a trade name “COLONATE HL” manufactured by Nippon Polyurethane Industry Co., Ltd.], and the like are also used. Moreover, examples of the epoxy-based crosslinking agents include N,N,N′,N′-tetraglycidyl-m-xylenediamine, diglycidylaniline, 1,3-bis(N,N-glycidylaminomethyl)cyclohexane, 1,6-hexanediol diglycidyl ether, neopentyl glycol diglycidyl ether, ethylene glycol diglycidyl ether, propylene glycol diglycidyl ether, polyethylene glycol diglycidyl ether, polypropylene glycol diglycidyl ether, sorbitol polyglycidyl ether, glycerol polyglycidyl ether, pentaerythritol polyglycidyl ether, polyglycerol polyglycidyl ether, sorbitan polyglycidyl ether, trimethylolpropnane polyglycidyl ether, adipic acid diglycidyl ester, o-phthalic acid diglycidyl ester, triglycidyl-tris(2-hydroxyethyl) isocyanurate, resorcin diglycidyl ether, and bisphenol-S-diglycidyl ether, and also epoxy-based resins having two or more epoxy groups in the molecule.

The amount of the crosslinking agent to be used is not particularly restricted and can be appropriately selected depending on the degree of the crosslinking. Specifically, it is preferable that the amount of the crosslinking agent to be used is usually 7 parts by weight or less (for example, 0.05 to 7 parts by weight) based on 100 parts by weight of the polymer component (particularly, a polymer having a functional group at the molecular chain end). When the amount of the crosslinking agent is larger than 7 parts by weight based on 100 parts by weight of the polymer component, the adhesive force is lowered, so that the case is not preferred. From the viewpoint of improving the cohesive force, the amount of the crosslinking agent is preferably 0.05 parts by weight or more based on 100 parts by weight of the polymer component.

In the invention, instead of the use of the crosslinking agent or together with the use of the crosslinking agent, it is also possible to perform a crosslinking treatment by irradiation with an electron beam, UV light, or the like.

The film for semiconductor back surface is preferably colored. Thereby, an excellent laser marking property and an excellent appearance property can be exhibited, and it becomes possible to make a semiconductor device having a value-added appearance property. As above, since the colored film for semiconductor back surface has an excellent marking property, marking can be performed to impart various kinds of information such as literal information and graphical information to the face on the non-circuit side of the semiconductor element or a semiconductor device using the semiconductor element by utilizing any of various marking methods such as a printing method and a laser marking method through the film for semiconductor back surface. Particularly, by controlling the color of coloring, it becomes possible to observe the information (for example, literal information and graphical information) imparted by marking with excellent visibility. Moreover, when the film for semiconductor back surface is colored, the dicing tape and the film for semiconductor back surface can be easily distinguished from each other, so that workability and the like can be enhanced. Furthermore, for example, as a semiconductor device, it is possible to classify products thereof by using different colors. In the case where the film for semiconductor back surface is colored (the case where the film is neither colorless nor transparent), the color shown by coloring is not particularly limited but, for example, is preferably dark color such as black, blue or red color, and black color is especially suitable.

In the present embodiment, dark color basically means a dark color having L*, defined in L*a*b* color space, of 60 or smaller (0 to 60), preferably 50 or smaller (0 to 50), and more preferably 40 or smaller (0 to 40).

Moreover, black color basically means a black-based color having L*, defined in L*a*b* color space, of 35 or smaller (0 to 35), preferably 30 or smaller (0 to 30), and more preferably 25 or smaller (0 to 25). In this regard, in the black color, each of a* and b*, defined in the L*a*b* color space, can be suitably selected according to the value of L*. For example, both of a* and b* are within the range of preferably −10 to 10, more preferably −5 to 5, and further preferably −3 to 3 (particularly 0 or about 0).

In the present embodiment, L*, a*, and b* defined in the L*a*b* color space can be determined by a measurement with a color difference meter (a trade name “CR-200” manufactured by Minolta Ltd; color difference meter). The L*a*b* color space is a color space recommended by the Commission Internationale de l'Eclairage (CIE) in 1976, and means a color space called CIE1976(L*a*b*) color space. Also, the L*a*b* color space is defined in Japanese Industrial Standards in JIS Z8729.

At coloring of the film for semiconductor back surface, according to an objective color, a colorant (coloring agent) can be used. As such a colorant, various dark-colored colorants such as black-colored colorants, blue-colored colorants, and red-colored colorants can be suitably used and black-colored colorants are more suitable. The colorant may be any of pigments and dyes. The colorant may be employed singly or in combination of two or more kinds. In this regard, as the dyes, it is possible to use any forms of dyes such as acid dyes, reactive dyes, direct dyes, disperse dyes, and cationic dyes. Moreover, also with regard to the pigments, the form thereof is not particularly restricted and can be suitably selected and used among known pigments.

In particular, when a dye is used as a colorant, the dye becomes in a state that it is homogeneously or almost homogeneously dispersed by dissolution in the film for semiconductor back surface, so that the film for semiconductor back surface having a homogeneous or almost homogeneous color density can be easily produced. Accordingly, when a dye is used as a colorant, the film for semiconductor back surface can have a homogeneous or almost homogeneous color density and can enhance a marking property and an appearance property.

The black-colored colorant is not particularly restricted and can be, for example, suitably selected from inorganic black-colored pigments and black-colored dyes. Moreover, the black-colored colorant may be a colorant mixture in which a cyan-colored colorant (blue-green colorant), a magenta-colored colorant (red-purple colorant), and a yellow-colored colorant (yellow colorant) are mixed. The black-colored colorant may be employed singly or in a combination of two or more kinds. Of course, the black-colored colorant may be used in combination with a colorant of a color other than black.

Specific examples of the black-colored colorant include carbon black (such as furnace black, channel black, acetylene black, thermal black, or lamp black), graphite, copper oxide, manganese dioxide, azo-type pigments (such as azomethine azo black), aniline black, perylene black, titanium black, cyanine black, active charcoal, ferrite (such as non-magnetic ferrite or magnetic ferrite), magnetite, chromium oxide, iron oxide, molybdenum disulfide, a chromium complex, a composite oxide type black pigment, and an anthraquinone type organic black pigment.

In the invention, as the black-colored colorant, black-colored dyes such as C.I. Solvent Black 3, 7, 22, 27, 29, 34, 43, 70, C.I. Direct Black 17, 19, 22, 32, 38, 51, 71, C.I. Acid Black 1, 2, 24, 26, 31, 48, 52, 107, 109, 110, 119, 154, and C.I. Disperse Black 1, 3, 10, 24; black-colored pigments such as C.I. Pigment Black 1, 7; and the like can also be utilized.

As such black-colored colorants, for example, a trade name “Oil Black BY”, a trade name “Oil Black BS”, a trade name “Oil Black HBB”, a trade name “Oil Black 803”, a trade name “Oil Black 860”, a trade name “Oil Black 5970”, a trade name “Oil Black 5906”, a trade name “Oil Black 5905” (manufactured by Orient Chemical Industries Co., Ltd.), and the like are commercially available.

Examples of colorants other than the black-colored colorant include cyan-colored colorants, magenta-colored colorants, and yellow-colored colorants. Examples of the cyan-colored colorants include cyan-colored dyes such as C.I. Solvent Blue 25, 36, 60, 70, 93, 95; C.I. Acid Blue 6 and 45; cyan-colored pigments such as C.I. Pigment Blue 1, 2, 3, 15, 15:1, 15:2, 15:3, 15:4, 15:5, 15:6, 16, 17, 17:1, 18, 22, 25, 56, 60, 63, 65, 66; C.I. Vat Blue 4, 60; and C.I. Pigment Green 7.

Moreover, among the magenta colorants, examples of magenta-colored dye include C.I. Solvent Red 1, 3, 8, 23, 24, 25, 27, 30, 49, 52, 58, 63, 81, 82, 83, 84, 100, 109, 111, 121, 122; C.I. Disperse Red 9; C.I. Solvent Violet 8, 13, 14, 21, 27; C.I. Disperse Violet 1; C.I. Basic Red 1, 2, 9, 12, 13, 14, 15, 17, 18, 22, 23, 24, 27, 29, 32, 34, 35, 36, 37, 38, 39, 40; C.I. Basic Violet 1, 3, 7, 10, 14, 15, 21, 25, 26, 27 and 28.

Among the magenta-colored colorants, examples of magenta-colored pigment include C.I. Pigment Red 1, 2, 3, 4, 5, 6, 7, 8, 9, 10, 11, 12, 13, 14, 15, 16, 17, 18, 19, 21, 22, 23, 30, 31, 32, 37, 38, 39, 40, 41, 42, 48:1, 48:2, 48:3, 48:4, 49, 49:1, 50, 51, 52, 52:2, 53:1, 54, 55, 56, 57:1, 58, 60, 60:1, 63, 63:1, 63:2, 64, 64:1, 67, 68, 81, 83, 87, 88, 89, 90, 92, 101, 104, 105, 106, 108, 112, 114, 122, 123, 139, 144, 146, 147, 149, 150, 151, 163, 166, 168, 170, 171, 172, 175, 176, 177, 178, 179, 184, 185, 187, 190, 193, 202, 206, 207, 209, 219, 222, 224, 238, 245; C.I. Pigment Violet 3, 9, 19, 23, 31, 32, 33, 36, 38, 43, 50; C.I. Vat Red 1, 2, 10, 13, 15, 23, 29 and 35.

Moreover, examples of the yellow-colored colorants include yellow-colored dyes such as C.I. Solvent Yellow 19, 44, 77, 79, 81, 82, 93, 98, 103, 104, 112, and 162; yellow-colored pigments such as C.I. Pigment Orange 31, 43; C.I. Pigment Yellow 1, 2, 3, 4, 5, 6, 7, 10, 11, 12, 13, 14, 15, 16, 17, 23, 24, 34, 35, 37, 42, 53, 55, 65, 73, 74, 75, 81, 83, 93, 94, 95, 97, 98, 100, 101, 104, 108, 109, 110, 113, 114, 116, 117, 120, 128, 129, 133, 138, 139, 147, 150, 151, 153, 154, 155, 156, 167, 172, 173, 180, 185, 195; C.I. Vat Yellow 1, 3, and 20.

Various colorants such as cyan-colored colorants, magenta-colored colorants, and yellow-colorant colorants may be employed singly or in a combination of two or more kinds, respectively. In this regard, in the case where two or more kinds of various colorants such as cyan-colored colorants, magenta-colored colorants, and yellow-colorant colorants are used, the mixing ratio (or blending ratio) of these colorants is not particularly restricted and can be suitably selected according to the kind of each colorant, an objective color, and the like.

In the case where the film 2 for semiconductor back surface is colored, the colored form is not particularly restricted. The film for semiconductor back surface may be, for example, a single-layer film-shaped article added with a coloring agent. Moreover, the film may be a laminated film where at least a resin layer formed of at least a thermosetting resin and a coloring agent layer are laminated. In this regard, in the case where the film 2 for semiconductor back surface is a laminated film of the resin layer and the coloring agent layer, the film 2 for semiconductor back surface in the laminated form preferably has a laminated form of a resin layer/a coloring agent layer/a resin layer. In this case, two resin layers at both sides of the coloring agent layer may be resin layers having the same composition or may be resin layers having different composition.

Into the film 2 for semiconductor back surface, other additives can be suitably blended according to the necessity. Examples of the other additives include an extender, an antiaging agent, an antioxidant, and a surfactant, in addition to a filler, a flame retardant, a silane-coupling agent, and an ion-trapping agent.

The filler may be any of an inorganic filler and an organic filler but an inorganic filler is suitable. By blending a filler such as an inorganic filler, imparting of electric conductivity to the film for semiconductor back surface, improvement of the thermal conductivity, control of elastic modulus, and the like can be achieved. In this regard, the film 2 for semiconductor back surface may be electrically conductive or non-conductive. Examples of the inorganic filler include various inorganic powders composed of silica, clay, gypsum, calcium carbonate, barium sulfate, alumina oxide, beryllium oxide, ceramics such as silicone carbide and silicone nitride, metals or alloys such as aluminum, copper, silver, gold, nickel, chromium, lead, tin, zinc, palladium, and solder, carbon, and the like. The filler may be employed singly or in a combination of two or more kinds. Particularly, the filler is suitably silica and more suitably fused silica. Herein, the average particle diameter of the inorganic filler is preferably within a range of from 0.1 μm to 80 μm. The average particle diameter of the inorganic filler can be measured, for example, by a laser diffraction-type particle size distribution measurement apparatus.

The blending amount of the filler (particularly, inorganic filler) is preferably 80 parts by weight or less (0 part by weight to 80 parts by weight), particularly preferably 0 part by weight to 70 parts by weight based on 100 parts by weight of the organic resin components.

Examples of the flame retardant include antimony trioxide, antimony pentoxide, and brominated epoxy resins. The flame retardant may be employed singly or in a combination of two or more kinds. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. The silane coupling agent may be employed singly or in a combination of two or more kinds. Examples of the ion-trapping agent include hydrotalcites and bismuth hydroxide. The ion-trapping agent may be employed singly or in a combination of two or more kinds.

The film 2 for semiconductor back surface can be, for example, formed by utilizing a customary method in which a thermosetting resin component such as an epoxy resin, optionally a thermoplastic resin component such as an acrylic resin, optionally, a solvent and other additives, and the like are mixed to prepare a resin composition and the composition is then formed into a film-shaped layer. Specifically, for example, the film-shaped layer (adhesive layer) as the film for semiconductor back surface can be formed by a method of applying the resin composition on the separator 42 to form a resin layer (or an adhesive layer); a method of applying the resin composition on a sheet for resin layer formation (for example, a release paper) to form a resin layer (or an adhesive layer), which is then transferred (transcribed) onto the separator 42; or the like. The resin composition may be a solution or a dispersion.

Since the film 2 for semiconductor back surface is formed of a resin composition containing a thermosetting resin such as an epoxy resin, in the film 2 for semiconductor back surface, the thermosetting resin is in an uncured or partially cured state at a stage before it is applied to the semiconductor element. In this case, after it is applied to the semiconductor element, the thermosetting resin in the film for semiconductor back surface is completely or almost completely cured. Specifically, in the case where the film 2 for semiconductor back surface is attached to the semiconductor element prior to the flip chip-bonding step, the thermosetting resin in the film for semiconductor back surface is completely or almost completely cured at the curing of the encapsulating material at the flip chip-bonding step. In the case where the film 2 for semiconductor back surface is attached to the semiconductor element after the flip chip-bonding step, for example, the thermosetting resin in the film for semiconductor back surface is completely or almost completely cured by the heat treatment to be performed after laser marking or the like (a reflow step to be performed after the laser marking).

As above, since the film for semiconductor back surface is in a state that the thermosetting resin is uncured or partially cured even when the film contains the thermosetting resin, the gel fraction of the film for semiconductor back surface is not particularly restricted but is, for example, suitably selected from the range of 50% by weight or less (0 to 50% by weight) and is preferably 30% by weight or less (0 to 30% by weight) and particularly preferably 10% by weight or less (0 to 10% by weight). The gel fraction of the film for semiconductor back surface can be measured by the following measuring method.

<Gel Fraction Measuring Method>

About 0.1 g of a sample is sampled from the film 2 for semiconductor back surface and precisely weighed (weight of sample) and, after the sample is wrapped in a mesh-type sheet, it is immersed in about 50 mL of toluene at room temperature for 1 week. Thereafter, a solvent-insoluble matter (content in the mesh-type sheet) is taken out of the toluene and dried at 130° C. for about 2 hours, the solvent-insoluble matter after drying is weighed (weight after immersion and drying), and a gel fraction (% by weight) is then calculated according to the following expression (a).

Gel fraction (% by weight)=[(Weight after immersion and Drying)/(Weight of sample)]×100 (a)

The gel fraction of the film for semiconductor back surface can be controlled by the kind and content of the resin components and the kind and content of the crosslinking agent and besides, heating temperature, heating time and the like.

In the invention, in the case where the film for semiconductor back surface is a film-shaped article formed of a resin composition containing a thermosetting resin such as an epoxy resin, close adhesiveness to a semiconductor wafer can be effectively exhibited.

In view of the fact that cutting water is used in the process of semiconductor device production, there may be the case where the film for semiconductor back surface has a water content of an ordinary state or more upon absorption of moisture. When heating is performed in such a high water content state as it is, there may be the case where water vapor remains at an adhesion interface between the film 2 for semiconductor back surface and the semiconductor element, thereby causing lifting. Accordingly, when the film for semiconductor back surface is configured to include a layer made of a core material with high moisture permeability on both surfaces, the water vapor is diffused, whereby such a problem can be avoided. From such a viewpoint, as the film for semiconductor back surface, there may be used a film having a multilayered structure in which a film for semiconductor back surface is formed on one surface or both surfaces of a core material. Examples of the core material include films (for example, a polyimide film, a polyester film, a polyethylene terephthalate film, a polyethylene naphthalate film, and a polycarbonate film), resin substrates reinforced with glass fibers or plastic-made nonwoven fibers, silicon substrates, and glass substrates.

The thickness (total thickness in the case of the laminated film) of the film 2 for semiconductor back surface is not particularly restricted but can be, for example, suitably selected from the range of about 2 μm to 200 μm. Furthermore, the thickness is preferably about 4 μm to 160 μm, more preferably about 6 μm to 100 μm, and particularly about 10 μm to 80 μm.

The tensile storage modulus B of the film 2 for semiconductor back surface at 23° C. before thermal curing preferably falls within a range of 0.01 to 4.0 GPa. The tensile storage modulus B of the film for semiconductor back surface 2 more preferably within a range of 0.05 to 3.5 GPa, further preferably within a range of 0.07 to 3.0 GPa. When the tensile storage modulus is 0.01 GPa or more, the film for semiconductor back surface can be cut into a prescribed width to form strips without deformation. On the other hand, when the tensile storage modulus is 4.0 GPa or less, the film can be cut into a prescribed width without cracking and chipping on the cut surface. As mentioned above, since the thermosetting resin is usually in an uncured or partially cured state, the tensile storage modulus B is usually a tensile storage modulus at 23° C. in the case where the thermosetting resin is in an uncured or partially cured state.

Incidentally, the tensile storage modulus is determined by preparing the film for semiconductor back surface in an uncured state and measuring an elastic modulus in a tensile mode under conditions of a sample width of 10 mm, a sample length of 22.5 mm, a sample thickness of 0.2 mm, a frequency of 1 Hz and a temperature elevating rate of 10° C./min under a nitrogen atmosphere at a prescribed temperature (23° C.) using a dynamic viscoelasticity measuring apparatus “Solid Analyzer RS A2” manufactured by Rheometrics Co., Ltd. and is taken as a value of obtained tensile storage modulus.

The elongation ratio A of the film 2 for semiconductor back surface at 23° C. before thermal curing preferably falls within a range of 1 to 700%. The elongation ratio A of the film 2 for semiconductor back surface is more preferably within a range of 1.5 to 600%, further preferably within a range of 2 to 500%. By controlling the elongation ratio A to 1% or more, the film 2 for semiconductor back surface can be suitably cut into a prescribed width to form strips. On the other hand, by controlling the elongation ratio A to 700% or less, the film for semiconductor back surface can be cut into a prescribed width to form strips without deformation. The elongation ratio A can be obtained by the method described in Examples.

Here, though the film 2 for semiconductor back surface may be a single layer or may be a laminated film in which a plurality of layers are laminated, in the case of the laminated film, the tensile storage modulus B may falls within a range of 0.01 to 4.0 GPa as a whole of the laminated film. Also, in the case of the laminated film, the elongation ratio A may falls with in a range of 1 to 700% as a whole of the laminated film. The foregoing elongation ratio A and tensile storage modulus B can be controlled by suitably setting up the kind and content of the resin components (thermoplastic resin and/or thermosetting resin), the kind and content of a filler such as a silica filler, and the like. Incidentally, in the case where the film 2 for semiconductor back surface is a laminated film in which a plurality of layers are laminated (in the case where the film for semiconductor back surface has a laminated form), as the laminated form, for example, a laminated form composed of a wafer adhesive layer and a laser marking layer and the like can be exemplified. Moreover, other layers (an intermediate layer, a light-blocking layer, a reinforcing layer, a coloring layer, a base material layer, an electromagnetic wave-blocking layer, a heat conducting layer, a pressure-sensitive adhesive layer, etc.) may be provided between the wafer adhesive layer and the laser marking layer. In this regard, the wafer adhesive layer is a layer exhibiting excellent close adhesiveness (adhesiveness) to the wafer and a layer which comes into contact with the back surface of the wafer. On the other hand, the laser marking layer is a layer exhibiting an excellent laser marking property and a layer to be utilized at the laser marking on the back surface of the semiconductor chip.

A light transmittance (visible light transmittance) of the film 2 for semiconductor back surface in a visible light region (wavelength: 400 nm to 800 nm) is not particularly restricted but is, for example, preferably 20% or less (0% to 20%), more preferably 10% or less (0% to 10%), and particularly preferably 5% or less (0% to 5%). When the visible light transmittance of the film 2 for semiconductor back surface is more than 20%, the semiconductor element may be adversely influenced due to light transmission. Moreover, the visible light transmittance (%) can be controlled by the kind and content of the resin components of the film 2 for semiconductor back surface, the kind and content of a coloring agent (a pigment, a dye, etc.), the content of an inorganic filler, and the like.

The visible light transmittance (%) of the film 2 for semiconductor back surface can be measured in the following manner. That is, the film 2 for semiconductor back surface having a thickness (average thickness) of 20 μm is prepared solely. Next, the film 2 for semiconductor back surface is irradiated with visible light having wave length of 400 nm to 800 nm [apparatus: a visible light-emitting apparatus (trade name “ABSORPTION SPECTRO PHOTOMETER”) manufactured by Shimadzu Corporation] at a prescribed intensity and intensity of the transmitted visible light is measured. Further, a value of the visible light transmittance can be determined from an intensity change before and after the visible light transmits through the film 2 for semiconductor back surface. In this regard, it is also possible to derive the visible light transmittance (%; wavelength: 400 nm to 800 nm) of the film 2 for semiconductor back surface having a thickness of 20 μm from the visible light transmittance (%; wavelength: 400 nm to 800 nm) of the film 2 for semiconductor back surface having a thickness of other than 20 μm. Also, the fact that the visible light transmittance (%) in the case of the film for semiconductor back surface having a thickness of 20 μm is determined in the present invention does not particularly restrict the thickness of the film 2 for semiconductor back surface to the film having a thickness of 20 μm.

Moreover, as the film 2 for semiconductor back surface, one having lower moisture absorbance is more preferred. Specifically, the moisture absorbance is preferably 1% by weight or less and more preferably 0.8% by weight or less. By regulating the moisture absorbance to 1% by weight or less, the laser marking property can be enhanced. Moreover, for example, the generation of voids between the film 2 for semiconductor back surface and the semiconductor element can be suppressed or prevented in the reflow step. The moisture absorbance is a value calculated from a weight change before and after the film 2 for semiconductor back surface is allowed to stand under an atmosphere of a temperature of 85° C. and a humidity of 85% RH for 168 hours. In the case where the film 2 for semiconductor back surface is formed of a resin composition containing a thermosetting resin, the moisture absorbance means a value obtained when the film after thermal curing is allowed to stand under an atmosphere of a temperature of 85° C. and a humidity of 85% RH for 168 hours. Moreover, the moisture absorbance can be regulated, for example, by changing the amount of the inorganic filler to be added.

Moreover, as the film 2 for semiconductor back surface, one having a smaller ratio of volatile matter is more preferred. Specifically, the ratio of weight decrease (weight decrease ratio) of the film 2 for semiconductor back surface after heating treatment is preferably 1% by weight or less and more preferably 0.8% by weight or less. The conditions for the heating treatment are, for example, a heating temperature of 250° C. and a heating time of 1 hour. By regulating the weight decrease ratio to 1% by weight or less, the laser marking property can be enhanced. Moreover, for example, the generation of cracks in a flip chip type semiconductor device can be suppressed or prevented in the reflow step. The weight decrease ratio can be regulated, for example, by adding an inorganic substance capable of reducing the crack generation at lead-free solder reflow. In the case where the film 2 for semiconductor back surface is formed of a resin composition containing a thermosetting resin component, the weight decrease ratio is a value obtained when the film for semiconductor back surface after thermal curing is heated under conditions of a temperature of 250° C. and a heating time of 1 hour.

The film 2 for semiconductor back surface is preferably wound as a roll in a form where a separator is laminated on one surface, i.e., in a form of the film 40 for semiconductor device production. Thereby, the surface on which the separator 42 of the film 2 for semiconductor back surface is not laminated can be brought into contact with the separator 42 positioned at the surface side (back surface of the separator 42) to protect the film for semiconductor back surface until actual use. Particularly, the film 2 for semiconductor back surface is attached to the semiconductor element after the film is cut according to the shape of the back surface of the semiconductor element to be attached. Therefore, it is more preferred that the film 40 for semiconductor device production is cut into a prescribed width according to the width (longitudinal width or transverse width) of the semiconductor element and is wound as a roll in a form of a strip film for semiconductor back surface. In this regard, the film 2 for semiconductor back surface may be wound as a roll in a form where a separator is laminated on both faces.

### (Separator)

As the separator 42, for example, suitable thin materials, e.g., paper-based base materials such as paper; fiber-based base materials such as fabrics, non-woven fabrics, felts, and nets; metal-based base materials such as metal foils and metal plates; plastic base materials such as plastic films and sheets; rubber-based base materials such as rubber sheets; foamed bodies such as foamed sheets; and laminates thereof [particularly, laminates of plastic based materials with other base materials, laminates of plastic films (or sheets) each other, etc.] can be used. In the invention, as the base material, plastic base materials such as plastic films and sheets can be suitably employed. Examples of raw materials for such plastic materials include olefinic resins such as polyethylene (PE), polypropylene (PP), and ethylene-propylene copolymers; copolymers using ethylene as a monomer component, such as ethylene-vinyl acetate copolymers (EVA), ionomer resins, ethylene-(meth)acrylic acid copolymers, and ethylene-(meth)acrylic acid ester (random, alternating) copolymers; polyesters such as polyethylene terephthalate (PET), polyethylene naphthalate (PEN), and polybutylene terephthalate (PBT); acrylic resins; polyvinyl chloride (PVC); polyurethanes; polycarbonates; polyphenylene sulfide (PPS); amide-based resins such as polyamides (Nylon) and whole aromatic polyamides (aramide); polyether ether ketones (PEEK); polyimides; polyetherimides; polyvinylidene chloride; ABS (acrylonitrile-butadiene-styrene copolymers); cellulose-based resins; silicone resins; and fluorinated resins. The separator 42 may be a single layer or a multilayer of two or more layers. After the separator 42 is cut according to the shape of the surface of the semiconductor element in a form of the film 40 for semiconductor device production together with the film 2 for semiconductor back surface, the separator 42 is attached to the semiconductor element together with the film 2 for semiconductor back surface. Thereafter, before or after the reflow step, the separator is peeled from the film 2 for semiconductor back surface. As a process for producing the separator 42, it can be formed by a conventionally known method.

The separator 42 may be subjected to releasing treatment on both surfaces. When both surfaces of the separator 42 are subjected to releasing treatment, the film 2 for semiconductor back surface can be wound as a roll in a form where a separator is laminated on one surface alone, i.e., in a form of the film 40 for semiconductor device production. Thus, at the cutting into a chip shape and attaching to the back surface of the chip, it is possible to omit the step of peeling the separator on another surface.

Examples of a releasing agent for use in the releasing treatment include fluorine-based releasing agents, long chain alkyl acrylate-based releasing agents, and silicone-based releasing agents. Of these, the silicone-based releasing agents are preferred. When the separator 42 is releasably treated with a silicone-based releasing agent, the separator 42 can be easily peeled from the film for semiconductor back surface.

The thickness of the separator 42 is not particularly limited but is preferably 7 to 400 μm, more preferably 10 to 300 μm, further preferably 20 to 200 μm.

The thickness of the film 40 for semiconductor device production (total thickness of the thickness of the film 2 for semiconductor back surface and the thickness of the separator 42) may be, for example, 9 to 600 μm, preferably 14 to 460 μm.

### (Producing Process of Film for Flip Chip Type Semiconductor Back Surface)

The film 2 for semiconductor back surface is obtained by applying a forming material for forming the film 2 for semiconductor back surface on a release paper so that the thickness after drying is a prescribed thickness and further drying the material under prescribed conditions.

### (Producing Process of Film for Semiconductor Device Production)

The film 2 for semiconductor back surface can be produced as follows in the case of the film 40 for semiconductor device production where the separator 42 is laminated on one surface thereof. For this case, the film 40 for semiconductor device production shown in FIG. 1 is explained as an example. First, the separator 42 can be formed by a conventionally known film-forming method. Examples of the film-forming method include a calendar film-forming method, a casting method in an organic solvent, an inflation extrusion method in a closely sealed system, a T-die extrusion method, a co-extrusion method, and a dry laminating method. Then, if necessary, one surface or both surfaces of the separator 42 is subjected to releasing treatment by coating the surface(s) with a releasing agent.

Next, a coated layer is formed by applying a forming material for forming the film 2 for semiconductor back surface onto a release paper so as to have a prescribed thickness after drying and further drying under prescribed conditions. The film 40 for semiconductor device production where the separator 42 is laminated on one surface of the film 2 for semiconductor back surface is obtained by transferring the coated layer onto the separator 42. In this regard, the film 40 for semiconductor device production can be also formed by directly applying the forming material for forming the film 2 for semiconductor back surface onto the separator 42, followed by drying under prescribed conditions (in the case that thermal curing is necessary, performing a heating treatment and drying according to needs). Incidentally, in the case that thermal curing is performed at the formation of the film 2 for semiconductor back surface, it is important to perform the thermal curing to such a degree that a partial curing is achieved but preferably, the thermal curing is not performed.

### (Semiconductor Wafer)

The semiconductor wafer is not particularly restricted as long as it is a known or commonly used semiconductor wafer and can be appropriately selected and used among semiconductor wafers made of various materials. In the invention, as the semiconductor wafer, a silicon wafer can be suitable used.

### (Production Process of Strip Film for Semiconductor Back Surface)

The strip film for semiconductor back surface can be obtained by cutting the film 2 for semiconductor back surface into a prescribed width. For such cutting, for example, a slitter or a cutting apparatus can be used. Since the ratio of the elongation ratio A at 23° C. before thermal curing to the tensile storage modulus B at 23° C. before thermal curing, i.e., the ratio A/B falls within a range of 1 to 8×10³ (%/GPa), the film 2 for semiconductor back surface has some degree of hardness and also has a property of some degree of stretchability. As a result, the film can be cut into a prescribed width with excellent width accuracy. In this regard, the strip film for semiconductor back surface may be cut into a prescribed width in a separator-attached state, i.e., in a state of the film 40 for semiconductor device production or may be cut into a prescribed width in a form of the strip film for semiconductor back surface alone.

### (Production Process of Semiconductor Device)

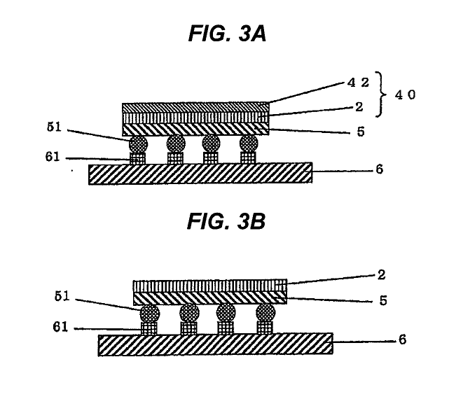

The process for producing a semiconductor device according to the invention is explained below with reference to FIGS. 2A to 2D and 3A to 3B. FIGS. 2A to 2D and 3A to 3B are cross-sectional schematic views each showing a process for producing a semiconductor device in the case of using the film for semiconductor device production shown in FIG. 1.

The semiconductor device according to the present embodiment can be produced using a strip film for semiconductor back surface produced by the foregoing production process of the strip film for semiconductor back surface. Specifically, the process comprises at least a step of attaching a semiconductor wafer onto a dicing tape, a step of dicing the semiconductor wafer, a step of picking up the semiconductor element obtained by dicing, a step of flip chip-connecting the semiconductor element onto an adherend, and a step of attaching the strip film for semiconductor back surface cut according to the shape of the back surface of the semiconductor element to the back surface of the semiconductor element.

### (Mounting Step)

First, as shown in FIG. 2A, the semiconductor wafer 4 is attached onto the hitherto known dicing tape 3 comprising a base material and a pressure-sensitive adhesive layer 32 provided on the base material 31 and is fixed thereon (mounting step). In this regard, the dicing tape 3 is attached to the back surface of the semiconductor wafer 4. The back surface of the semiconductor wafer 4 means a surface (also referred to as non-circuit surface, non-electrode-formed surface, or the like) opposite to the circuit surface. The attaching method is not particularly limited but a method by press adhesion is preferred. The press adhesion is usually performed while pressing with a pressing means such as a pressing roll.

### (Dicing Step)

Next, as shown in FIG. 2B, the semiconductor wafer 4 is diced. Consequently, the semiconductor wafer 4 is cut into a prescribed size and individualized (is formed into small pieces) to produce semiconductor chips 5. The dicing is performed according to a normal method from the circuit surface side of the semiconductor wafer 4, for example. Moreover, the present step can adopt, for example, a cutting method called full-cut that forms a slit reaching the dicing tape 3. The dicing apparatus used in the present step is not particularly limited, and a conventionally known apparatus can be used.

In the case where the dicing tape 3 is expanded, the expansion can be performed using a conventionally known expanding apparatus. The expanding apparatus has a doughnut-shaped outer ring capable of pushing the dicing tape 3 downward through a dicing ring and an inner ring which has a diameter smaller than the outer ring and supports the dicing tape 3. Owing to the expanding step, it is possible to prevent the damage of adjacent semiconductor chips through contact with each other in the picking-up step to be mentioned later.

### (Picking-Up Step)

Picking-up of the semiconductor chip 5 is performed as shown in FIG. 2C to peel the semiconductor chip 5 from the dicing tape 3 in order to collect the semiconductor chip 5 that is adhered and fixed to the dicing tape 3. The method of picking-up is not particularly limited, and conventionally known various methods can be adopted. For example, there may be mentioned a method including pushing up each semiconductor chip 5 from the base material 31 side of the dicing tape 3 with a needle and picking-up the pushed semiconductor chip 5 with a picking-up apparatus.

### (Flip Chip Connecting Step)

The picked-up semiconductor chip 5 is fixed on an adherend such as a substrate according to a flip chip bonding method (flip chip mounting method), as shown in FIG. 2D. Concretely, the semiconductor chip 5 is fixed on the adherend 6 according to an ordinary method in such a manner that the circuit face of the semiconductor chip 5 (this may be referred to as a front surface, a circuit pattern formed surface or an electrode formed surface) could face the adherend 6. For example, while the bump 51 formed on the circuit surface side of the semiconductor chip 5 is pressed against the bonding conductive material (e.g., solder) 61 attached to the connecting pad of the adherend 6, the conductive material is melted to secure the electric connection between the semiconductor chip 5 and the adherend 6 and the semiconductor chip 5 is thereby fixed to the adherend 6 (flip chip-bonding step). In this case, gaps are formed between the semiconductor chip 5 and the adherend 6, and the gap distance may be generally from 30 μm to 300 μm or so. After the semiconductor chip 5 has been flip chip-bonded (flip chip-connected) onto the adherend 6, it is important that the interface and the gaps between the semiconductor chip 5 and the adherend 6 are cleaned up and the two are sealed up by filling the gaps with an encapsulating material (e.g., encapsulating resin).

As the adherend 6, various substrates such as lead frames and circuit boards (such as wiring circuit boards) can be used. The material of the substrates is not particularly restricted and there may be mentioned ceramic substrates and plastic substrates. Examples of the plastic substrates include epoxy substrates, bismaleimide triazine substrates, and polyimide substrates.

In the flip chip bonding step, the material of the bump and the conductive material is not particularly restricted and examples thereof include solders (alloys) such as tin-lead-based metal materials, tin-silver-based metal materials, tin-silver-copper-based metal materials, tin-zinc-based metal materials, and tin-zinc-bismuth-based metal materials, and gold-based metal materials and copper-based metal materials.

Incidentally, in the flip chip bonding step, the conductive material is melted to connect the bump at the circuit face side of the semiconductor chip 5 and the conductive material on the surface of the adherend 6. The temperature at the melting of the conductive material is usually about 260° C. (e.g., 250° C. to 300° C.).

In the present step, it is preferred to wash the opposing face (electrode-formed face) between the semiconductor chip 5 and the adherend 6 and the gaps. The washing liquid to be used at the washing is not particularly restricted and examples thereof include organic washing liquids and aqueous washing liquids.

Next, an encapsulation step is performed for encapsulating the gaps between the flip chip-bonded semiconductor chip 5 and the adherend 6. The encapsulation step is performed using an encapsulating resin. The encapsulation conditions on this occasion are not particularly restricted but the curing of the encapsulating resin is usually carried out at 175° C. for 60 seconds to 90 seconds. However, in the invention, without limitation thereto, the curing may be performed at a temperature of 165 to 185° C. for a few minutes, for example.

The encapsulating resin is not particularly restricted as long as the material is a resin having an insulating property (an insulating resin) and may be suitably selected and used among known encapsulating materials such as encapsulating resins. The encapsulating resin is preferably an insulating resin having elasticity. Examples of the encapsulating resin include resin compositions containing an epoxy resin. As the epoxy resin, there may be mentioned the epoxy resins exemplified in the above. Furthermore, the encapsulating resin composed of the resin composition containing an epoxy resin may contain a thermosetting resin other than an epoxy resin (such as a phenol resin) or a thermoplastic resin in addition to the epoxy resin. Incidentally, a phenol resin can be utilized also as a curing agent for the epoxy resin and, as such a phenol resin, there may be mentioned phenol resins exemplified in the above.

Then, the strip film for semiconductor back surface is cut according to the shape of the back surface of the semiconductor chip 5. The cutting can be performed by means of a punching blade such as Thomson blade or laser.

Next, as shown in FIG. 3A, the cut strip film for semiconductor back surface fitted with the separator 42 (individualized film 40 for semiconductor device production) is attached to the back surface of the semiconductor chip 5.

Then, as shown in FIG. 3B, the separator 42 is peeled from the film 40 for semiconductor device production attached to the back surface of the semiconductor chip 5.

In the semiconductor device (flip chip-mounted semiconductor device) manufactured using the film 40 for semiconductor device production, the film for semiconductor back surface is attached to the back surface of the semiconductor chip, and therefore, various marking can be applied with excellent visibility. In particular, even when the marking method is a laser marking method, marking can be applied with an excellent contrast ratio, and it is possible to observe various kinds of information (for example, literal information and graphical information) applied by laser marking with good visibility. At the laser marking, a known laser marking apparatus can be utilized. Moreover, as the laser, it is possible to utilize various lasers such as a gas laser, a solid-state laser, and a liquid laser. Specifically, as the gas laser, any known gas lasers can be utilized without particular limitation but a carbon dioxide laser (CO₂ laser) and an excimer laser (ArF laser, KrF laser, XeCl laser, XeF laser, etc.) are suitable. As the solid-state laser, any known solid-state lasers can be utilized without particular limitation but a YAG laser (such as Nd:YAG laser) and a YVO₄ laser are suitable.

After the laser marking of the film 2 for semiconductor back surface, a heat treatment (reflow step to be performed after the laser marking) may be performed according to need. Conditions for the heat treatment are not particularly limited, but it can be performed in accordance with the standard of JEDEC Solid State Technology Association (JEDEC). For example, it can be performed at a temperature (upper limit) within a range of 210 to 270° C. for a time within a range of 5 to 50 seconds. By the step, the semiconductor package can be mounted on a substrate (such as a mother board).

In the aforementioned production process of the semiconductor device, there is explained the case where the film 2 for semiconductor back surface (film 40 for semiconductor device production) is attached to the back surface of the semiconductor chip 5 after the encapsulating step for encapsulating the gap between the semiconductor chip 5 flip chip-bonded and the adherend 6. However, in the invention, the timing of attaching the film for flip chip type semiconductor back surface to the back surface of the semiconductor chip is not limited to the example and, for example, the timing may be before the encapsulating step.

In the aforementioned production process of the semiconductor device, there is explained the case where the film 2 for semiconductor back surface fitted with the separator 42 (individualized film 40 for semiconductor device production) is attached to the back surface of the semiconductor chip 5, but in the invention, without limitation to the example, the film for flip chip type semiconductor back surface cut according to the shape of the back surface of the semiconductor element may be attached solely to the back surface of the semiconductor element.

Since the semiconductor device produced using the film for semiconductor device production of the invention is a semiconductor device mounted by the flip chip mounting method, the device has a thinned and miniaturized shape as compared with a semiconductor device mounted by a die-bonding mounting method. Thus, the semiconductor devices can be suitably employed as various electronic devices and electronic parts or materials and members thereof. Specifically, as the electronic devices in which the flip chip-mounted semiconductor devices of the invention are utilized, there may be mentioned so-called “mobile phones” and “PHS”, small-sized computers [e.g., so-called “PDA” (handheld terminals), so-called “notebook-sized personal computer”, so-called “Net Book (trademark)”, and so-called “wearable computers”, etc.], small-sized electronic devices having a form where a “mobile phone” and a computer are integrated, so-called “Digital Camera (trademark)”, so-called “digital video cameras”, small-sized television sets, small-sized game machines, small-sized digital audio players, so-called “electronic notepads”, so-called “electronic dictionary”, electronic device terminals for so-called “electronic books”, mobile electronic devices (portable electronic devices) such as small-sized digital type watches, and the like. Needless to say, electronic devices (stationary type ones, etc.) other than mobile ones, e.g., so-called “desktop personal computers”, thin type television sets, electronic devices for recording and reproduction (hard disk recorders, DVD players, etc.), projectors, micromachines, and the like may be also mentioned. In addition, electronic parts or materials and members for electronic devices and electronic parts are not particularly restricted and examples thereof include parts for so-called “CPU” and members for various memory devices (so-called “memories”, hard disks, etc.).

### EXAMPLES

The following will illustratively describe preferred Examples of the invention in detail. However, the materials, the mixing amounts, and the like described in these Examples are not intended to limit the scope of the invention to only those unless otherwise stated, and they are merely explanatory examples. Moreover, part in each example is a weight standard unless otherwise stated.

### Example 1

### <Preparation of Film for Flip Chip Type Semiconductor Back Surface>

40 parts of a phenoxy resin (trade name “EP4250” manufactured by JER Co., Ltd.), 129 parts of a phenol resin (trade name “MEH-8000” manufactured by Meiwa Chemical Co., Ltd.), 1137 parts of a spherical silica (trade name “SO-25R” manufactured by Admatechs Company Limited), 14 parts of a dye (trade name “OIL BLACK BS” manufactured by Orient Chemical Industries Co., Ltd.), and 1 part of a thermal curing-accelerating catalyst (trade name “2PHZ-PW” manufactured by Shikoku Chemicals Corporation) based on 100 parts of an epoxy resin (trade name “HP4032D” manufactured by DIC, Inc.) were dissolved in methyl ethyl ketone to prepare a solution of a resin composition (sometimes referred to as “resin composition solution A”) having a solid concentration of 23.6% by weight.

The resin composition solution A was applied on a first separator composed of a polyethylene terephthalate film having a thickness of 50 μm, which had been subjected to a silicone-releasing treatment, and dried at 130° C. for 2 minutes. Then, a second separator composed of a polyethylene terephthalate film having a thickness of 50 μm, which had been subjected to a silicone-releasing treatment, was attached thereto at 60° C. to prepare a film for flip chip type semiconductor back surface (sometimes referred to as “film A for semiconductor back surface”) having a thickness of 20 μm.

### Example 2

### <Preparation of Film for Flip Chip Type Semiconductor Back Surface>

48 parts of an epoxy resin (trade name “EPIKOTE 1004” manufactured by JER Co., Ltd.), 55 parts of a phenol resin (trade name “MIREX XLC-4L” manufactured by Mitsui Chemicals, Inc.), 135 parts of a spherical silica (trade name “SO-25R” manufactured by Admatechs Company Limited), 5 parts of Dye 1 (trade name “OIL GREEN 502” manufactured by Orient Chemical Industries Co., Ltd.), and 5 parts of Dye 2 (trade name “OIL BLACK BS” manufactured by Orient Chemical Industries Co., Ltd.) based on 100 parts of an acrylic acid ester-based polymer (trade name “PARACRON W-197CM” manufactured by Negami Chemical Industrial Co., Ltd.) having ethyl acrylate and methyl methacrylate as main components were dissolved in methyl ethyl ketone to prepare a solution of a resin composition (sometimes referred to as “resin composition solution B”) having a solid concentration of 23.6% by weight.

The resin composition solution B was applied on a first separator composed of a polyethylene terephthalate film having a thickness of 50 μm, which had been subjected to a silicone-releasing treatment, and dried at 130° C. for 2 minutes. Then, a second separator composed of a polyethylene terephthalate film having a thickness of 50 μm, which had been subjected to a silicone-releasing treatment, was attached thereto at 60° C. to prepare a film for flip chip type semiconductor back surface (sometimes referred to as “film B for semiconductor back surface”) having a thickness of 20 μm.

### Example 3

### <Preparation of Film for Flip Chip Type Semiconductor Back Surface>

12 parts of an epoxy resin (trade name “EPIKOTE 1004” manufactured by JER Co., Ltd.), 13 parts of a phenol resin (trade name “MIREX XLC-4L” manufactured by Mitsui Chemicals, Inc.), 180 parts of a spherical silica (trade name “SO-25R” manufactured by Admatechs Company Limited), 5 parts of Dye 1 (trade name “OIL GREEN 502” manufactured by Orient Chemical Industries Co., Ltd.), and 5 parts of Dye 2 (trade name “OIL BLACK BS” manufactured by Orient Chemical Industries Co., Ltd.) based on 100 parts of an acrylic acid ester-based polymer (trade name “PARACRON W-197CM” manufactured by Negami Chemical Industrial Co., Ltd.) having ethyl acrylate and methyl methacrylate as main components were dissolved in methyl ethyl ketone to prepare a solution of a resin composition (sometimes referred to as “resin composition solution C”) having a solid concentration of 23.6% by weight.

The resin composition solution C was applied on a first separator composed of a polyethylene terephthalate film having a thickness of 50 μm, which had been subjected to a silicone-releasing treatment, and dried at 130° C. for 2 minutes. Then, a second separator composed of a polyethylene terephthalate film having a thickness of 50 μm, which had been subjected to a silicone-releasing treatment, was attached thereto at 60° C. to prepare a film for flip chip type semiconductor back surface (sometimes referred to as “film C for semiconductor back surface”) having a thickness of 20 μm.

### Comparative Example 1

### <Preparation of Film for Flip Chip Type Semiconductor Back Surface>

113 parts of an epoxy resin (trade name “EPIKOTE 1004” manufactured by JER Co., Ltd.), 121 parts of a phenol resin (trade name “MIREX XLC-4L” manufactured by Mitsui Chemicals, Inc.), 246 parts of a spherical silica (trade name “SO-25R” manufactured by Admatechs Company Limited), 5 parts of Dye 1 (trade name “OIL GREEN 502” manufactured by Orient Chemical Industries Co., Ltd.), and 5 parts of Dye 2 (trade name “OIL BLACK BS” manufactured by Orient Chemical Industries Co., Ltd.) based on 100 parts of an acrylic acid ester-based polymer (trade name “PARACRON W-197CM” manufactured by Negami Chemical Industrial Co., Ltd.) having ethyl acrylate and methyl methacrylate as main components were dissolved in methyl ethyl ketone to prepare a solution of a resin composition (sometimes referred to as “resin composition solution D”) having a solid concentration of 23.6% by weight.

The resin composition solution D was applied on a first separator composed of a polyethylene terephthalate film having a thickness of 50 μm, which had been subjected to a silicone-releasing treatment, and dried at 130° C. for 2 minutes. Then, a second separator composed of a polyethylene terephthalate film having a thickness of 50 μm, which had been subjected to a silicone-releasing treatment, was attached thereto at 60° C. to prepare a film for flip chip type semiconductor back surface (sometimes referred to as “film D for semiconductor back surface”) having a thickness of 20 μm.

### (Evaluation)

For the films for flip chip type semiconductor back surface prepared in Examples 1 to 3 and Comparative Example 1, a tensile storage modulus, an elongation ratio, and a slit property were evaluated or measured according to the following evaluation or measurement methods. The evaluation or measurement results are also listed in Table 1.

### <Measurement of Tensile Storage Modulus at 23° C. Before Thermal Curing>

The tensile storage modulus B of the film for flip chip type semiconductor back surface at 23° C. before thermal curing was measured by preparing a film for flip chip type semiconductor back surface as single one and measuring the modulus using a dynamic viscoelasticity measuring apparatus “Solid Analyzer RS A2” manufactured by Rheometrics Co., Ltd. The sample for the measurement was one having a sample width of 10 mm, a sample length of 22.5 mm, and a sample thickness of 0.2 mm. The measurement conditions were a frequency of 1 Hz and a temperature elevating rate of 10° C./min in a tensile mode under a nitrogen atmosphere at 23° C.

### <Measurement of Elongation Ratio at 23° C. Before Thermal Curing>

The elongation ratio A of the film for flip chip type semiconductor back surface at 23° C. before thermal curing was measured by preparing a film for flip chip type semiconductor back surface alone and measuring the ratio using a dynamic viscoelasticity measuring apparatus “Solid Analyzer RS A2” manufactured by Rheometrics Co., Ltd. The sample for the measurement was one having a sample width of 10 mm, a sample length of 20 mm, and a sample thickness of 0.2 mm. The measurement was performed at a tensile rate of 50 mm/s using the dynamic viscoelasticity measuring apparatus with holding the sample so that the distance between upper and lower chucks was 10 mm, and an obtained value of the elongation ratio at breaking point was taken as an elongation ratio A.

### <Evaluation Method of Slit Property>

Using each of the films for flip chip type semiconductor back surface according to Examples and Comparative Example, the film was cut into a width of 9 mm by a slitter to prepare a strip film for wafer back surface protection. The cutting condition for the slitter was 20 m/min.

### (Evaluation Standard for Slit Property)

Good: Chipping or cracking was not generated on edge of the film for flip chip type semiconductor back surface after slitting.

Bad: Chipping or cracking was generated on edge of the film for flip chip type semiconductor back surface after slitting.

TABLE 1

| | Elongation | Tensile storage | |
|---|---|---|---|
| | ratio A before | modulus B before | |
| | thermal curing (%) | thermal curing (GPa) | Slit property |
| Example 1 | 4 | 3.0 | Good |
| Example 2 | 200 | 1.3 | Good |
| Example 3 | 500 | 0.07 | Good |
| Comparative | 1 | 4.0 | Bad |
| Example 1 | | | |

While the present invention has been described in detail and with reference to specific embodiments thereof, it will be apparent to one skilled in the art that various changes and modifications can be made therein without departing from the scope thereof.

This application is based on Japanese patent application No. 2010-169559 filed Jul. 28, 2010, the entire contents thereof being hereby incorporated by reference.

What is claimed is:

1. A film for flip chip type semiconductor back surface to be formed on a back surface of a semiconductor element flip chip-connected onto an adherend,
the film for flip chip type semiconductor back surface having a ratio of A/B falling within a range of 1 to 8×10³ (%/GPa), wherein A is an elongation ratio (%) of the film for flip chip type semiconductor back surface at 23° C. before thermal curing and B is a tensile storage modulus (GPa) of the film for flip chip type semiconductor back surface at 23° C. before thermal curing,
wherein the film for flip chip type semiconductor back surface contains a black-colored colorant.

2. The film for flip chip type semiconductor back surface according to claim 1, wherein the tensile storage modulus falls within a range of 0.01 to 4.0 GPa.

3. The film for flip chip type semiconductor back surface according to claim 1,
wherein the film for flip chip type semiconductor back surface contains an epoxy resin and a phenol resin,
wherein a total amount of the epoxy resin and the phenol resin falls within a range of 5 to 90% by weight based on the total resin components of the film for flip chip type semiconductor back surface, and
wherein the epoxy resin and the phenol resin each have a melting point of 25° C. or lower.

4. The film for flip chip type semiconductor back surface according to claim 2,
wherein the film for flip chip type semiconductor back surface contains an epoxy resin and a phenol resin,
wherein a total amount of the epoxy resin and the phenol resin falls within a range of 5 to 90% by weight based on the total resin components of the film for flip chip type semiconductor back surface, and
wherein the epoxy resin and the phenol resin each have a melting point of 25° C. or lower.

5. A process for producing a strip film for semiconductor back surface, the process comprising cutting the film for flip chip type semiconductor back surface according to claim 1 into a prescribed width to obtain the strip film for semiconductor back surface.

6. The process for producing a strip film for semiconductor back surface according to claim 5, wherein the tensile storage modulus falls within a range of 0.01 to 4.0 GPa.

7. The process for producing a strip film for semiconductor back surface according to claim 5,
wherein the film for flip chip type semiconductor back surface contains an epoxy resin and a phenol resin,
wherein a total amount of the epoxy resin and the phenol resin falls within a range of 5 to 90% by weight based on the total resin components of the film for flip chip type semiconductor back surface, and
wherein the epoxy resin and the phenol resin each have a melting point of 25° C. or lower.

8. The process for producing a strip film for semiconductor back surface according to claim 6,
wherein the film for flip chip type semiconductor back surface contains an epoxy resin and a phenol resin,
wherein a total amount of the epoxy resin and the phenol resin falls within a range of 5 to 90% by weight based on the total resin components of the film for flip chip type semiconductor back surface, and
wherein the epoxy resin and the phenol resin each have a melting point of 25° C. or lower.

9. A flip chip type semiconductor device, which is manufactured using the strip film for semiconductor back surface produced by the process for producing a strip film for semiconductor back surface according to claim 5.

10. The flip chip type semiconductor device according to claim 9, wherein the tensile storage modulus falls within a range of 0.01 to 4.0 GPa.

11. The flip chip type semiconductor device according to claim 9,
wherein the film for flip chip type semiconductor back surface contains an epoxy resin and a phenol resin,
wherein a total amount of the epoxy resin and the phenol resin falls within a range of 5 to 90% by weight based on the total resin components of the film for flip chip type semiconductor back surface, and
wherein the epoxy resin and the phenol resin each have a melting point of 25° C. or lower.

12. The flip chip type semiconductor device according to claim 10,
wherein the film for flip chip type semiconductor back surface contains an epoxy resin and a phenol resin,
wherein a total amount of the epoxy resin and the phenol resin falls within a range of 5 to 90% by weight based on the total resin components of the film for flip chip type semiconductor back surface, and
wherein the epoxy resin and the phenol resin each have a melting point of 25° C. or lower.
